(19) United States
(12) Patent Application Publication
(10) Pub. No.: US 2015/0017758 A1
(43) Pub. Date: Jan. 15, 2015

(54) SYSTEMS, METHODS, AND MEDIA FOR LASER DEPOSITION

(71) Applicants: Mikhael Reginevich, Brest (BY); Stanislau Herasimenka, Tempe, AZ (US)

(72) Inventors: Mikhael Reginevich, Brest (BY); Stanislau Herasimenka, Tempe, AZ (US)

(21) Appl. No.: 14/329,650

(22) Filed: Jul. 11, 2014

Related U.S. Application Data
(60) Provisional application No. 61/844,984, filed on Jul. 11, 2013.

(51) Int. Cl. H01L 31/18; C23C 14/28; C23C 14/16

(52) U.S. Cl. CPC H01L 31/18; C23C 14/16; C23C 14/28
USPC 438/98; 118/726; 427/597

(57) ABSTRACT

In accordance with some embodiments of the disclosed subject matter, mechanisms for pulsed laser deposition are provided. In some embodiments, a system for pulsed laser deposition is provided, the system comprising: a pulsed laser configured to project a pulsed laser beam at a rotating target material and cause metal clusters to be ablated from the rotating target material; and a confinement mechanism configured to control deposition of the metal clusters on a substrate.

### CROSS-REFERENCE TO RELATED APPLICATIONS

This application claims the benefit of U.S. Provisional Patent Application No. 61/844,984, filed Jul. 11, 2013, which is hereby incorporated by reference herein in its entirety.

### TECHNICAL FIELD

The disclosed subject matter relates to systems, methods, and media for pulsed laser deposition.

### BACKGROUND

Several existing metallization methods and other techniques, such as pulsed laser deposition, laser metal drilling, screen printing, etc., are used for manufacturing silicon solar cells.

However, in many instances, existing metallization methods and other techniques suffer from technical issues, such as heating and melting of the sputtered area in the sputtering process, liquid droplet formation, emissions and waste treatment, high electricity consumption, and so on.

Accordingly, it is desirable to provide new mechanisms for pulsed laser deposition.

### SUMMARY

In accordance with some embodiments of the disclosed subject matter, mechanisms for pulsed laser deposition are provided. In some embodiments, a system for pulsed laser deposition is provided, the system comprising: a pulsed laser configured to project a pulsed laser beam at a rotating target material and cause metal clusters to be ablated from the rotating target material; and a confinement mechanism configured to control deposition of the metal clusters on a substrate.

In some embodiments, a method for pulsed laser deposition is provided, the method comprising: rotating a target material; projecting a pulsed laser beam at the rotating target material to cause metal clusters to be ablated from the rotating target material; and performing confinement to control deposition of the metal clusters on a substrate.

In some embodiments, a non-transitory computer-readable medium containing computer-executable instructions that, when executed by a processor, cause the processor to perform a method for pulsed laser deposition is provided, the method comprising: setting a rotation speed of a rotating target material; setting parameters for a pulsed laser that is configured to project a pulsed laser beam at the target material and cause metal clusters to be ablated from the target material; and setting parameters for a confinement mechanism to control deposition of the metal clusters on a substrate.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 is a schematic diagram of pulsed laser deposition in accordance with some embodiments of the disclosed subject matter.

FIG. 2 is a schematic diagram of pulsed laser deposition using electrical discharging in accordance with some embodiments of the disclosed subject matter.

FIG. 3 is a fragmentary view showing an expanded view of pulsed laser deposition using electrostatic lensing for focusing in accordance with some embodiments of the disclosed subject matter.

FIG. 4 is a fragmentary view showing an expanded view of pulsed laser deposition using magnetic lensing for focusing in accordance with some embodiments of the disclosed subject matter.

FIG. 5 is a front view showing examples of solar cells with front metal grids that are formed by pulsed laser deposition in accordance with some embodiments of the disclosed subject matter.

FIG. 6 is a schematic diagram of an example of hardware that can be used for pulsed laser deposition in accordance with some embodiments of the disclosed subject matter.

FIG. 7 shows an example of a process for performing pulsed laser deposition in accordance with some embodiments of the disclosed subject matter.

### DETAILED DESCRIPTION

In accordance with various embodiments, as described in more details below, mechanisms (which can be systems, methods, and/or media) for pulsed laser deposition are provided.

In some embodiments, the mechanisms described herein can ablate metal clusters from a rotating target using a pulsed laser beam. In some embodiments, the ablation rate can be controlled by adjusting the energy level, frequency, polarization, and pulse width of the laser pulses.

In some embodiments, the mechanisms described herein can focus a plume of ionized metal clusters by using electrostatic lensing, magnetic lensing, electrical discharging, and/or the combination thereof. In some embodiments, the mechanisms described herein can maintain the ionization of the plume of ionized metal clusters by using a focused continuous laser to heat the plume.

In some embodiments, the mechanisms described herein can use the plume of ionized metal clusters to form a deposition on a substrate. In some embodiments, this deposition method can be used for solar cell front metal grid designs. In some embodiments, with a suitably high ablation rate, a throughput of approximately one cell per second can be realized.

In some embodiments, the mechanism described herein can be used in 3D printing to manufacture metal tools and components.

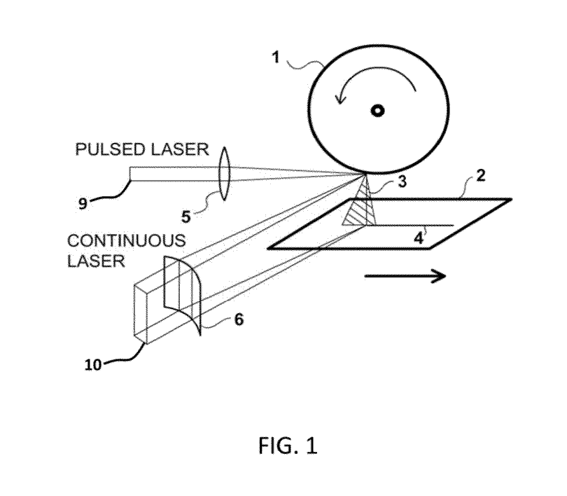

Turning to FIG. 1, a schematic diagram of pulsed laser deposition is shown in accordance with some embodiments of the disclosed subject matter. As illustrated, metal clusters 3 are ablated from a rotating target 1 using a pulsed laser beam 9 generated by a suitable laser light source (not shown). In some embodiments, pulsed laser beam 9 can be focused on target 1 using one or more lenses 5.

In some embodiments, target 1 can be any suitable metal material such as copper (Cu) and silver (Ag). In some embodiments, the ablation regime can be tuned to ablate the metal material of target 1 predominately or entirely in the form of ions. In some embodiments, a resulting plume of ionized metal clusters 3 can be focused (not shown in FIG. 1) using any suitable focusing mechanism, such as electrical discharge, one or more electrostatic lenses, one or more magnetic lenses, and/or any other suitable focusing mechanism.

In some embodiments, ionized metal clusters 3 can next arrive at substrate 2 due to the target rotation and form a deposit 4 on substrate 2. The ionization of metal clusters 3 in the plume can be maintained by a continuous laser beam 10 generated by another laser light source (not shown) focused by cylindrical lens 6 and/or any other suitable lens. In some embodiments, the continuous laser beam 10 can be used to heat plume all the way from target 1 to substrate 2, and thereby form a channel of ionized material.

In some embodiments, pulsed laser deposition from the rotating target in accordance with the mechanisms described herein can achieve <30 μm resolution and 0.01 g/second ablation rate. These mechanisms can be used to form fine line metallization features in various microelectronic applications. For example, these mechanisms can be used to create 30 μm wide, 20 μm tall copper (Cu) metallization grids for silicon solar cells or to deposit various components used in printed electronics.

In some embodiments, these mechanisms can be used in applications sensitive to heating and mechanical pressure. For example, these mechanisms can be applied to silicon hetero junction solar cells on 50 μm wafers and/or to organic electronic devices. In some embodiments, these mechanisms can be used in three-dimensional (3D) printing to manufacture metal tools and components.

In accordance with some embodiments, picosecond (ps) or femtosecond (fs) long (e.g., 100 fs to 30 ps) high energy pulses (e.g., pulses with fluences higher than the threshold fluence for a particular material (e.g., Cu)) with a top-hat beam profile and p-polarization at a MHz (e.g., 0.1-10 MHz) frequency that are spatially decoupled with the ionized plume can be used as pulsed laser beam 9. In some embodiments, the laser fluence can be close to the threshold fluence for evaporation in order to convert the pulse energy more efficiently (e.g., so as to use the energy to evaporate the material rather than heating it). For example, for a copper target material, the fluence can be approximately 0.2 J/cm² for Cu in some embodiments. In some embodiments, high Cu flux can be achieved by maintaining a large ablation area, while keeping the fluence at or near the ablation threshold level. In some embodiments, the ps or fs pulse approach can also be used to mitigate the technical issue of liquid droplet formation.

In some embodiments, a primary pulse train of pulsed laser beam 9 can be accompanied by supplemental long pre-pulses (not shown) that pre-heat the material to reduce the binding energy and to increase its absorption coefficient. The supplemental long pre-pulses can be provided by the same laser or another laser with lower energy pulses in some embodiments.

In some embodiments, beam shaping can be used to shape pulsed laser beam 9 for achieving a top-hat beam profile that avoids sub-threshold energy transfer (from the tails of a Gaussian beam profile) to target 1. This can improve energy conversion efficiency and improve the plume quality by tightening up the distribution of the ablated material in the plume. Using fs or ps pulses (e.g., up to 20 ps long) and a top-hat beam as pulsed laser beam 9 may also improve the ionization fraction of the ablated plume.

In some embodiments, the pulse repetition rate of pulsed laser beam 9 can be set to increase the mass conversion rate (from solid to vapor) of ablation of target 1. Any suitable pulse repetition rate can be used in some embodiments. For example, a pulse repetition rate of 0.1-10 MHz can be used in some embodiments. A high pulse repetition rate may enable a high ablation rate, and ultimately, a high mass transfer rate from the target to the substrate. A high mass transfer rate may also better support the formation of electrical discharge, which can be used to focus the Cu plume onto the substrate.

In some embodiments, the beam incident angle of pulsed laser beam 9 can be adjusted so that the beam is spatially isolated from the ablation plume in order to avoid and/or reduce problems associated with the plume shielding the beam from the ablation crater.

In some embodiments, the ablated material can be maintained in an ionized form, which can then facilitate applying electro-magnetic confinement. In some embodiments, maintaining the ablated material in ionized form can be achieved by tuning the ablation regime to ablate the material, predominantly in the form of ions, and maintaining ionization of the material as it travels from the target to the substrate by a supplementary continuous wave laser beam 10.

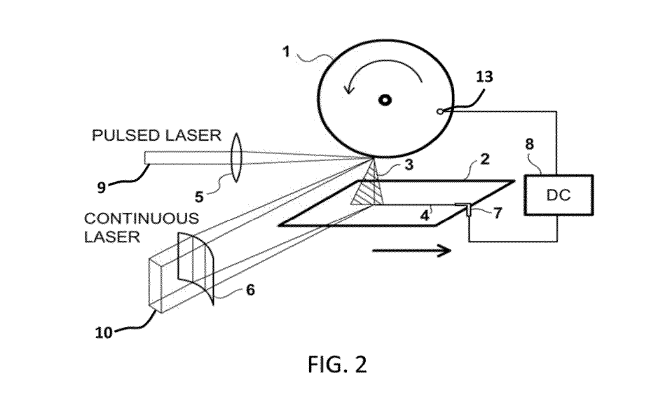

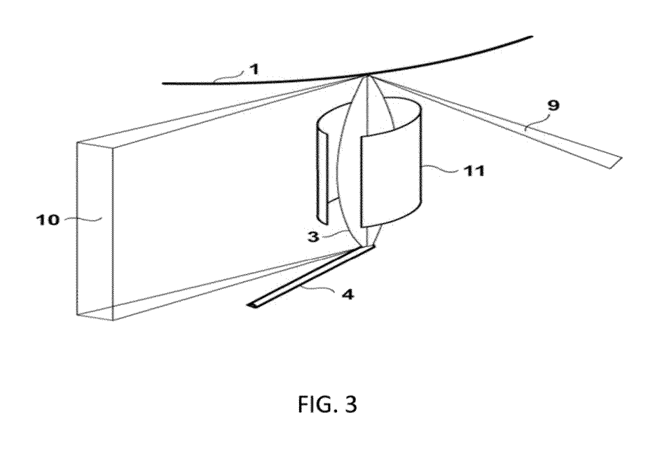

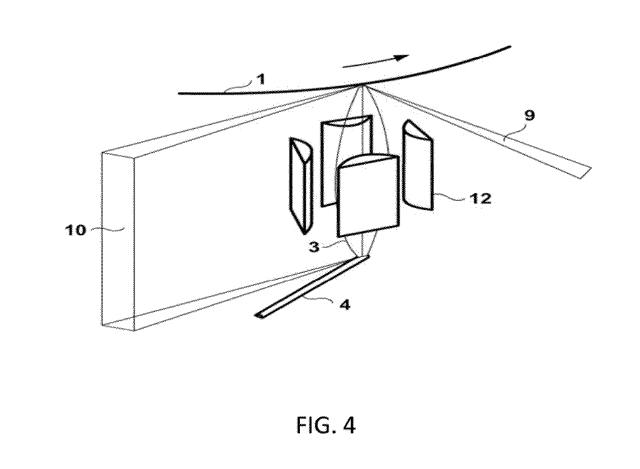

In some embodiments, selective deposition of the ablated material by using electro-magnetic confinement mechanisms can be used. These mechanisms can include the formation of an electrical discharge between target 1 and substrate 2 (e.g., as described in connection with FIG. 2), the use of electrostatic lensing (e.g., as described in connection with FIG. 3), the use of magnetic lensing (e.g., as described in connection with FIG. 4), and/or any other suitable mechanism for electromagnetic confinement, and/or any suitable combination of the same.

In some embodiments, when using electrical discharge, as shown in FIG. 2, a high voltage power supply 8 having any suitable voltage output(s) can be configured so that a negative probe 7 of the supply is connected to the edge of a solar cell (or any other suitable substrate) and a positive probe 13 of the supply is connected to the target. An electrical discharge from the power supply can then be used to ignite a discharge arc between target 1 and substrate 2. Once the discharge arc is ignited, the current through the discharge arc can then be maintained by a high current (which can have any suitable value) provided by the same or a different power supply (different power supply not shown).

In some embodiments, when this technique is applied to a conventional diffused junction solar cell, the negative probe can be connected to one or more preliminary ablated tracks in silicon nitride antireflection coating. In some embodiments, the discharge current can be configured to flow only through an opening in silicon nitride and thereby narrow ablation plume 3 and result in selective deposition.

In some embodiments, an electrical discharge current may result in heating of substrate 2. Therefore, in such embodiments, water cooling, Peltier cooling, and/or any other suitable cooling technique can be applied to the substrate carrier to prevent thermal damage.

In some embodiments, selective deposition of the ablated material can be performed using electrostatic lensing (e.g., as shown in FIG. 3) or magnetic lensing (e.g., as shown in FIG. 4). In some embodiments, electrostatic lenses 11 (FIG. 3), or Einzel lenses, and magnetic lenses 12 (FIG. 4) can be used to focus beams of charged particles. For example, such lenses can be used in the cathode ray tubes or in focused ion beam tools. In some embodiments, in electrostatic lensing, a high voltage can be applied to cylindrical metal plates as shown in FIG. 3 to create an electrostatic deflecting that causes ions to move toward a focal point of the lens. In some embodiments, one or more electromagnetic lenses can be designed as magnetic lenses 12 to focus currents of metal clusters as shown in FIG. 4.

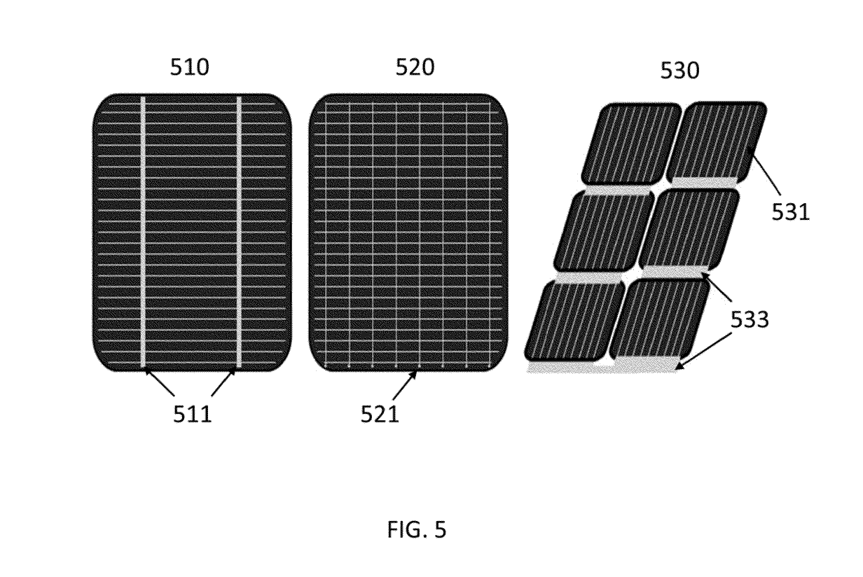

FIG. 5 shows examples of solar cells with front metal grids that can be generated by the mechanisms described herein in accordance with some embodiments. In some embodiments, the mechanisms described herein can be used to form a metal grid for solar cell interconnections in a photo voltaic (PV) module and improve module performance. For example, in some embodiments, bus bars 511 can be deposited with thicknesses equivalent to the thickness of solar cell ribbons, thus eliminating the necessity to solder ribbons along an entire cell. In some embodiments, short interconnect ribbons that are soldered to thick bus bars only at the edge of a solar cell can be used to interconnect the solar cell to one or more other solar cells. In some embodiments, 1 mm wide and 100 μm tall bus bars can be deposited to achieve low series resistance.

In some embodiments, as illustrated in example 520, eight bus bars 521 each with a 300 μm width and a 50 μm height and with 2 mm circular contacts near the edge of the solar cell can be deposited. Using a larger number of narrow bus bars can be beneficial because doing so can reduce the length of the fingers, and thereby relax the requirement on their width. Thus, in some embodiments, 30 μm wide, 20 μm tall fingers can be enabled without the necessity to substantially reduce finger spacing. In some embodiments, using a larger number of narrow bus bars can also allow less shading, since the cumulative width of thin bus bars can be as low as 1 mm. Optimization of bus bars design can achieve an overall 1% absolute efficiency increase due to fewer optical losses and resistive losses. In some embodiments, the cells can be interconnected by Cu foils soldered to the circular contacts at the edge of the cells.

In some embodiments, as illustrated in example 530, bus bars 531 can be deposited so that bus bars 531 extend past the cell boundary and can be used as interconnects. For example, in some embodiments, thick Cu bus bars 531 can be deposited on a polymer film 533 applied at the edge of a solar cell. Cu lines can then be disconnected from the polymer film 533 to serve as interconnects.

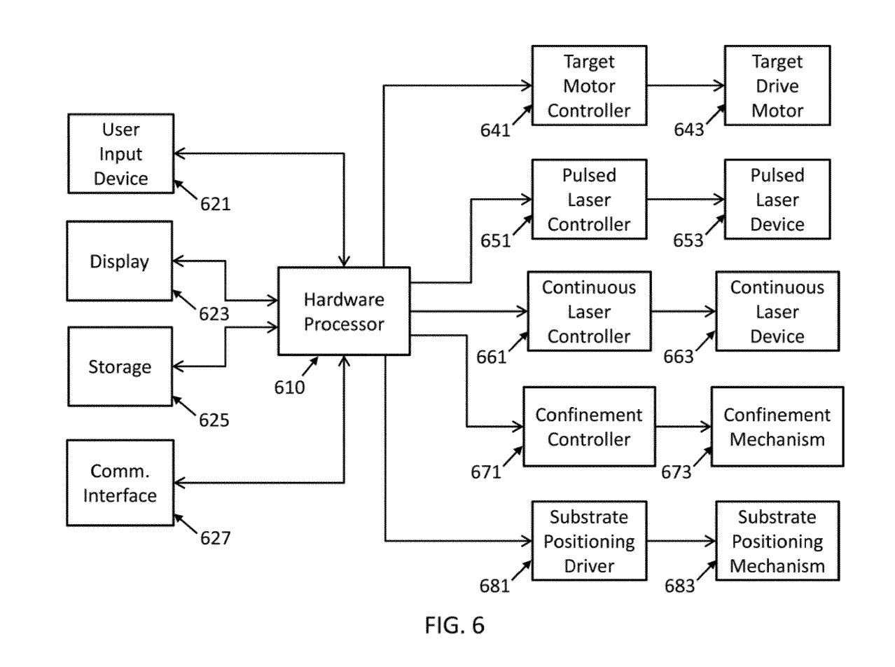

FIG. 6 shows an example of hardware that can be used in accordance with some embodiments. As illustrated, this hardware can include a hardware processor 610, which can be any suitable hardware processor, such as a microprocessor, a microcontroller, a programmable logic device, a digital signal processor, dedicated logic, and/or any other suitable device capable of controlling functions as described herein.

In some embodiments, hardware processor 610 can be implemented as a general purpose device such as a computer or a special purpose device such as a client, a server, etc. Any of these general or special purpose devices can include any suitable components such as a microprocessor, digital signal processor, a controller, etc., memory, communication interfaces, display controllers, input devices, etc.

In some embodiments, hardware processor 610 may be coupled to a target motor controller 641 which controls a target drive motor 643. Target drive motor 643 may cause the target to rotate. Target motor controller 641 may control the speed at which the motor rotates the target and when the motor starts and stops.

In some embodiments, hardware processor 610 may also be coupled to a pulsed laser controller 651 which controls a pulsed laser device 653. Pulsed laser device 653 may generate any suitable pulsed laser as described herein. Pulsed laser controller 651 may be any suitable mechanism for providing suitable control over the parameters of the generated pulsed laser as described herein. For example, pulsed laser controller 651 may control when the pulsed laser is triggered to ablate the target, the pulse width of the pulsed laser, the pulse repetition rate of the pulsed laser, the frequency of the pulsed laser, the power level of the pulsed laser, the configuration of any lensing associated with the pulsed laser (e.g., to control the pulsed laser's position with respect to the target), and/or any other suitable parameter(s).

In some embodiments, hardware processor 610 may also be coupled to a continuous laser controller 661 which controls a continuous laser device 663. Continuous laser device 663 may generate any suitable continuous laser as described herein. Continuous laser controller 661 may be any suitable mechanism for providing suitable control over the parameters of the generated continuous laser as described herein. For example, continuous laser controller 661 may control when the continuous laser is on, the output power of the continuous laser, the frequency of the continuous laser, the configuration of any lensing associated with the continuous laser (e.g., to control the continuous laser's position with respect to the ablation plume), and/or any other suitable parameter(s).

In some embodiments, hardware processor 610 may also be coupled to a confinement controller 671 which controls a confinement mechanism 673. Confinement mechanism 673 may be any suitable confinement mechanism as described herein. Confinement controller 671 may be any suitable mechanism for providing suitable control over the parameters of confinement mechanism 673 as described herein.

In some embodiments, hardware processor 610 may also be coupled to a substrate positioning driver 681 which controls a substrate positioning mechanism 683. In some embodiments, substrate positioning mechanism 683 may be any suitable position mechanism, such as an X-Y positioning table. Substrate positioning driver 681 may be any suitable mechanism for providing drive signals and for controlling the positioning of substrate positioning mechanism 683.

In some embodiments, hardware processor 610 may also be coupled to one or more input devices 621 (such as a keyboard, a mouse, a track pad, an optical input interface (e.g., for detecting target ablation, confinement, deposition, etc.), an audio input interface, any suitable feedback from any of the above-mentioned components of the hardware, and/or any other suitable input), a display 623 (e.g., such as an LCD display, an LED display, etc.), storage 625 (e.g., such as memory (e.g., RAM, ROM, flash, etc.), a hard disk, etc.), and a communication interface 627 (e.g., such as a wired communication interface (e.g., ethernet, USB, serial, parallel, optical, etc.) or a wireless communication interface (e.g., such as WiFi, satellite, mobile data network, etc.).

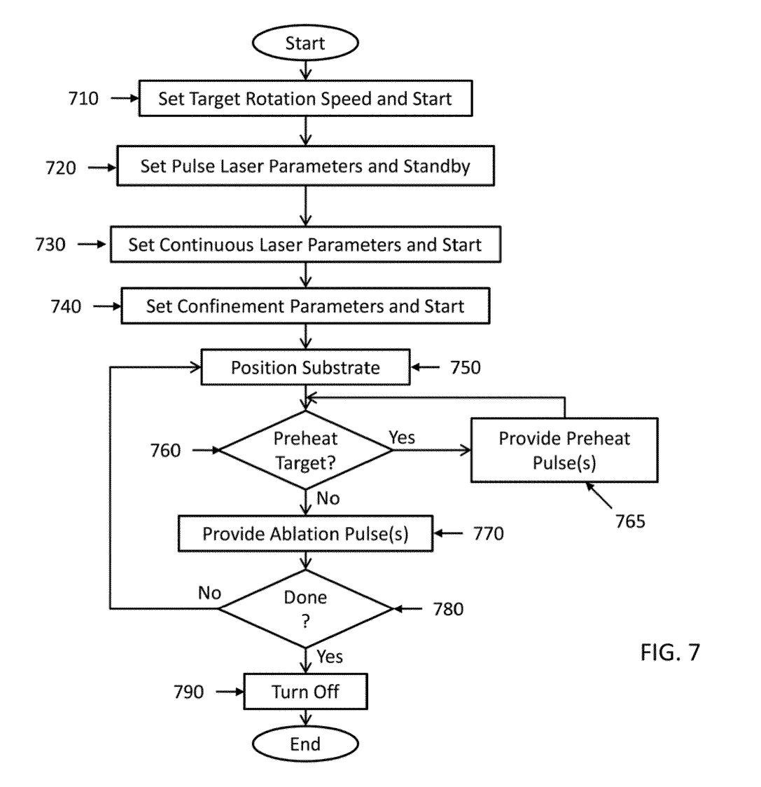

Turning to FIG. 7, an example of a process for performing pulsed laser deposition as described herein is provided. In some embodiments, this process can run in the hardware processor and software for performing this process can be stored in the storage.

After the process begins, at 710, the process can set the target rotation speed and start the target drive motor as described above. Next, at 720, the process can set the pulsed laser parameters as described above and set the pulsed laser to standby. Then, at 730, the process can set the continuous laser parameters and start the continuous laser as described above. Next, at 740, the process can set the confinement parameters and start the confinement mechanism as described above. Then, at 750, the process can determine whether to preheat the target. This determination can be made on any suitable basis. If it is determined to preheat the target (“Yes” at 760), the process can cause the pulsed laser to provide one or more preheat pulses at 765 as described above, and then re-determine whether to preheat the target at 760. After determining that the target does not need to be preheated or to be preheated any further (“No” at 760), the process can provide one or more ablation pulses at 770 as described above. Next, at 780, the process can determine whether the process is done. If not (“No” at 780), the process can re-position the substrate at 750 and repeat the subsequent steps as described above. Otherwise (“Yes” at 780), the process can turn off the components at 790 and end.

It should be noted that the above steps of the flow diagram of FIG. 7 can be executed or performed in any suitable order or sequence not limited to the order and sequence shown and described in the figure. Also, some of the above steps of the flow diagram of FIG. 7 can be executed or performed substantially simultaneously where appropriate or in parallel to reduce latency and processing times. Furthermore, it should be noted that FIG. 7 is provided as an example only. At least some of the steps shown in the figure may be performed in a different order than represented, performed concurrently, or altogether omitted.

In some embodiments, any suitable computer readable media can be used for storing instructions for performing the processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although the invention has been described and illustrated in the foregoing illustrative embodiments, it is understood that the present disclosure has been made only by way of example, and that numerous changes in the details of embodiment of the invention can be made without departing from the spirit and scope of the invention, which is only limited by the claims which follow. Features of the disclosed embodiments can be combined and rearranged in various ways.

What is claimed is:

1. A system for pulsed laser deposition comprising:
a pulsed laser configured to project a pulsed laser beam at a rotating target material and cause metal clusters to be ablated from the rotating target material; and
a confinement mechanism configured to control deposition of the metal clusters on a substrate.

2. The system of claim 1, further comprising a continuous laser configured to project a continuous laser beam at an ablation plume between the rotating target material and the substrate.

3. The system of claim 1, wherein the substrate is a photovoltaic cell.

4. The system of claim 1, wherein the rotating target material is copper.

5. The system of claim 1, wherein the confinement mechanism includes at least one of:
an electrostatic lens;
a magnetic lens; and
an electrical discharging power source.

6. The system of claim 1, wherein the pulsed laser beam has at least one feature of the following:
picosecond order pulse width;
femtosecond order pulse width;
a top-hat beam profile;
p-polarization;
MHz order frequency; and
spatially decoupled with the ablation plume.

7. The system of claim 1, wherein the pulsed laser beam is also configured to produce supplemental long pre-pulses to pre-heat the target material.

8. A method for pulsed laser deposition, the method comprising:
rotating a target material;
projecting a pulsed laser beam at the rotating target material to cause metal clusters to be ablated from the rotating target material; and
performing confinement to control deposition of the metal clusters on a substrate.

9. The method of claim 8, further comprising projecting a continuous laser beam at an ablation plume between the rotating target material and the substrate.

10. The method of claim 8, wherein the substrate is a photovoltaic cell.

11. The method of claim 8, wherein the target material is copper.

12. The method of claim 8, wherein the confinement mechanism includes at least one of:
an electrostatic lens;
a magnetic lens; and
an electrical discharging power source.

13. The method of claim 8, wherein the pulsed laser beam has at least one feature of the following:
picosecond order pulse width;
femtosecond order pulse width;
a top-hat beam profile;
p-polarization;
MHz order frequency; and
spatially decoupled with the ablation plume.

14. The method of claim 8, further comprising pre-heating the target material.

15. A non-transitory computer-readable medium containing computer-executable instructions that, when executed by a processor, cause the processor to perform a method for pulsed laser deposition, the method comprising:
setting a rotation speed of a target material;
setting parameters for a pulsed laser that is configured to project a pulsed laser beam at the target material and cause metal clusters to be ablated from the target material; and
setting parameters for a confinement mechanism to control deposition of the metal clusters on a substrate.

16. The non-transitory computer-readable medium of claim 15, further comprising setting parameters for a continuous laser that is configured to project a continuous laser beam at an ablation plume between the target material and the substrate.

17. The non-transitory computer-readable medium of claim 15, wherein the substrate is a photovoltaic cell.

18. The non-transitory computer-readable medium of claim 15, wherein the rotating target material is copper.

19. The non-transitory computer-readable medium of claim 15, wherein the confinement mechanism includes at least one of:
an electrostatic lens;
an magnetic lens; and
an electrical discharging power source.

20. The non-transitory computer-readable medium of claim 15, wherein the pulsed laser beam has at least one feature of the following:
picosecond order pulse width;
femtosecond order pulse width;
a top-hat beam profile;
p-polarization;
MHz order frequency; and
spatially decoupled with the ablation plume.

21. The non-transitory computer-readable medium of claim 15, wherein the method further comprises pre-heating the target material.
